(19) United States
(12) Patent Application Publication
(10) Pub. No.: US 2014/0042489 A1
(43) Pub. Date: Feb. 13, 2014

(54) Lighting Device and Method for Producing a Lighting Device

(71) Applicant: Thomas Preuschl, Sinzing (DE)

(72) Inventor: Thomas Preuschl, Sinzing (DE)

(73) Assignee: OSRAM GMBH, Muenchen (DE)

(21) Appl. No.: 14/111,207

(22) PCT Filed: Apr. 3, 2012
(86) PCT No.: PCT/EP2012/056103

§ 371 Date: Oct. 11, 2013

(30) Foreign Application Priority Data
Apr. 29, 2011 (DE) 102011017790.6

(51) Int. Cl. H01L 33/64; H01L 33/00

(52) U.S. Cl. CPC H01L 33/64; H01L 33/005
USPC 257/99; 438/26

(57) ABSTRACT

A lighting device may include: at least one semiconductor light source, at least one printed circuit board which is populated with at least one component for operating the at least one semiconductor light source, wherein at least one component is embedded into the printed circuit board.

### RELATED APPLICATIONS

This application is a national stage entry according to 35 U.S.C. §371 of PCT application No.: PCT/EP2012/056103 filed on Apr. 3, 2012, which claims priority from German application No.: 10 2011 017 790.6 filed on Apr. 29, 2011.

### TECHNICAL FIELD

Various embodiments relate to a lighting device, including at least one semiconductor light source, in particular light emitting diode, and at least one printed circuit board which is populated with at least one component for operating the at least one semiconductor light source. Various embodiments furthermore relate to a method for manufacturing such a lighting device.

### BACKGROUND

LED modules hitherto have been comparatively large and have not been standardized. This makes it considerably more difficult to implement concepts involving identical parts for LED modules.

### SUMMARY

Various embodiments provide a lighting device, including at least one semiconductor light source and at least one printed circuit board, wherein the printed circuit board is populated with at least one component for operating the at least one semiconductor light source, and wherein at least one component is embedded into the printed circuit board.

This lighting device has the advantage that it enables a compact lighting device. Moreover, the printed circuit board, despite different components, can be configured in an externally identical or at least very similar fashion, which facilitates its integration into standardized environments.

This enables an improved application of concepts involving identical parts.

In one development, the printed circuit board is a multilayer printed circuit board, which enables a high integration density and a particularly compact design.

In one specific development, the at least one embedded component is electrically connected to the at least one semiconductor light source by means of at least one printed circuit board plated-through hole (an electrical line in the printed circuit board which electrically connects different levels of the multilayer printed circuit board to one another, in particular a “via”) running at least partly within the printed circuit board. In this regard, simple and short electrical connections can be produced in particular in the case of a multilayer printed circuit board.

Preferably, the at least one semiconductor light source includes at least one light emitting diode. In the event of a plurality of light emitting diodes being present, they can emit light in the same color or in different colors. A color can be monochromatic (e.g. red, green, blue, etc.) or multichromatic (e.g. white). Moreover, the light emitted by the at least one light emitting diode can be an infrared light (IR LED) or an ultraviolet light (UV LED). A plurality of light emitting diodes can generate a mixed light; e.g. a white mixed light. The at least one light emitting diode can contain at least one wavelength-converting phosphor (conversion LED). Alternatively or additionally, the phosphor can be arranged in a manner remote from the light emitting diode (“remote phosphor”). The at least one light emitting diode can be present in the form of at least one individually housed light emitting diode or in the form of at least one LED chip. A plurality of LED chips can be mounted on a common substrate (“submount”) or else directly on a heat sink. The at least one light emitting diode can be equipped with at least one dedicated and/or common optical unit for beam guiding, e.g. at least one Fresnel lens, collimator, and so on. Instead of or in addition to inorganic light emitting diodes, e.g. on the basis of InGan or AlInGaP, organic LEDs (OLEDs, e.g. polymer OLEDs) can generally also be used. Alternatively, the at least one semiconductor light source can include e.g. at least one diode laser.

The at least one component can be, in particular, an electrical or electronic component. The at least one component can be, in particular, a housed or an unhoused component. The housed component can be, for example, an integrated circuit or an electrical component (resistor, inductance or coil, capacitance or capacitor, etc.).

The fact that the at least one component is embedded into the printed circuit board can mean, in particular, that at least one component is printed onto the printed circuit board or onto a layer of the (single-layered or multilayered) printed circuit board and/or that at least one component is arranged between two layers of a multilayer printed circuit board. Printing, in particular, enables a robust and compact design of the printed circuit board.

A printed circuit board wiring can be situated on the outer surface of the printed circuit board and/or, in the case of a multilayer printed circuit board, between two adjacent layers of the multilayer printed circuit board. Electrical connections between different levels of the printed circuit board wiring can be realized, in particular, by means of the printed circuit board plated-through holes between the levels. At least one, preferably a plurality, of the printed circuit board plated-through holes extend(s) as far as at least one of the two outer surfaces in order to enable electrical contact to be made with the environment (in particular with a power supply, the at least one semiconductor light source, etc.).

In one configuration, all the components are embedded in the printed circuit board. In this regard, a particularly robust printed circuit board that can readily be fitted into a receptacle can be provided. Moreover, such a printed circuit board can be standardized uniformly and particularly well with regard to its outer contour.

Alternatively, at least one non-embedded component, in particular housed component, may also be fitted to an outer side of the printed circuit board which is not provided for mechanical contact-making, e.g. in a receptacle.

In yet another alternative, non-embedded components may also be arranged at both outer sides of the printed circuit board.

In another configuration, the at least one printed circuit board is a ceramic printed circuit board. The ceramic printed circuit board has the advantage of a high electrical insulation in conjunction with a high thermal conductivity. As a result, long creepage paths can be achieved without high structural outlay. In addition, dedicated electrical insulation layers can thus be dispensed with. Particularly on a ceramic substrate, high voltage ranges, e.g. up to 450 volts, can be implemented without further measures. In this regard, high-voltage ranges and/or low-voltage ranges, etc. can be implemented on the ceramic substrate without further measures.

In one development, the multilayer printed circuit board is a low temperature cofired ceramics (LTCC) multilayer printed circuit board. The latter has the advantage that printed components or components embedded in some other way can be integrated into the printed circuit board in a particularly simple manner. Moreover, LTCC multilayer printed circuit boards can be produced cost-effectively.

In another development, the multilayer printed circuit board is a high temperature cofired ceramics (HTCC) multilayer printed circuit board.

However, the printed circuit board may also include a base material of the CEM type (“Composite Epoxy Material”, e.g. CEM-1 to CEM-5), of the FR type (“flame retardant”, e.g. FR1 to FR5, in particular FR4) or in the form of polyimide. Polyimide has the advantage of high elastic flexibility or deformation.

In one configuration, furthermore, the at least one printed circuit board is a multilayer printed circuit board having prepreg layers on the outer side. Such a multilayer printed circuit board has the advantage that it can be produced without firing. A prepreg (“preimpregnated fibers”) layer can be understood to mean, in particular, a layer which consists of continuous fibers and an uncured thermosetting plastic matrix. The prepreg layer may also consist of thermosetting plastic fiber matrix semifinished product such as BMC (“Bulk Molding Compound”) or SMC (“Sheet Molding Compound”). A further advantage is that, by means of the prepreg layer, conventional printed circuit boards that have already been populated can also be covered on the outer side.

The exterior prepreg layers can cover, in particular, a single-layered or a multilayed printed circuit board whose base material differs from the prepreg material. In this regard, the non-covered printed circuit board may be a metal-core circuit board. Alternatively, the base material of the non-covered printed circuit board may include or consist of a CEM (“Composite Epoxy Material”, e.g. CEM-1 to CEM-5) material, an FR material (“flame retardant”, e.g. FR1 to FR5, in particular FR4) or a ceramic.

In one configuration, moreover, the at least one semiconductor light source is arranged at a side of the printed circuit board. In this regard, a particularly compact lighting device can be provided. By way of example, a connection plug, at least one electrical and/or electronic component and/or a housing can also be arranged on the same side.

In an alternative configuration, the lighting device includes a housing, at the front side of which the at least one semiconductor light source is arranged and at the rear side of which a receptacle for accommodating the printed circuit board is present. This configuration has the advantage that the housing enables high dissipation of heat from the at least one semiconductor light source. Moreover, a high mechanical stability and very accurate production accuracy, in particular with regard to an orientation of the at least one semiconductor light source, are thus provided. The printed circuit board can therefore be fitted into the receptacle, which can be achieved in a particularly simple manner in the case of mechanical contact-making at regions not populated with components.

In another configuration, the housing has at least one channel from the receptacle to that side at which the at least one semiconductor light source is arranged, and the printed circuit board has at least one elongate electrical conduction element which is laid in at least one channel and which electrically connects the at least one component to the at least one semiconductor light source. An easily implementable and short electrical connection between the at least one semiconductor light source and the printed circuit board is thus provided. Moreover, such a lighting device can be produced in a particularly simple manner. The channel can be, in particular, a vertical drilled hole.

The at least one elongate electrical conduction element can be at least one cable, for example. The at least one cable can be guided e.g. in a cable sleeve. The at least one elongate electrical conduction element can, however, also be an electrically conductive pin (hollow pin or solid pin), for example, which affords the advantage of a high mechanical stability and, consequently, simple insertion into the channel. The pin may have a bondable plane, for example, to which a bonding wire can be fixed, in particular for the purpose of fixing a bonding wire. The bonding wire can electrically connect in particular the pin to the at least one semiconductor light source. For this purpose, the bonding wire may in particular also be connected to a contact area (“bonding pad”) of the at least one semiconductor light source or a wiring connected thereto. The bondable plane can correspond, in particular, to a top area of the pin.

The electrical conduction element can also be wired by means of other methods, e.g. by means of a coplanar connection.

At that side of the housing into which the opposite side of the channel relative to the receptacle opens, the elongate electrical conduction element can be electrically connected to the at least one semiconductor light source directly or indirectly (e.g. by means of further electrical or electronic components). In this regard, a cable may be soldered or the like to a semiconductor light source or a contact zone electrically connected (directly or indirectly) thereto. The pin may be connected to a contact zone of the housing e.g. by means of a bonding wire.

The at least one elongate electrical conduction element can be fixed to the printed circuit board for example by means of a press-fit fixture. A press-fit fixture or press-fit connection on one side or on both sides is possible, particularly if the base material of the printed circuit board and/or the substrate of the at least one semiconductor light source are/is an FR material, in particular FR4. Alternatively, the electrical conduction element may be welded or soldered onto a bondable area or connection area of the printed circuit board.

In yet another configuration, the housing is a housing having good thermal conductivity, in particular metal housing. A metal housing can be produced precisely and inexpensively and has a high coefficient of thermal conductivity. The metal can include, in particular, aluminum, high-grade steel and/or copper. Alternatively, the housing may consist of ceramic or of a material containing elemental carbon (e.g. graphite, carbon black, carbon nanotubes, etc.). A housing having good thermal conductivity can be, in particular, a housing having a thermal conductivity of 15 W/(m·K) or more, in particular of 100 W/(m·K) or more.

In one development, if the housing is electrically conductive, the elongate electrical conduction element is electrically insulated from the housing, e.g. by means of an electrically insulating sleeve.

In yet another configuration, the lighting device is a lighting module. The lighting module may be interconnected in particular with a dedicated power supply and/or with other lighting modules. However, the lighting device can also be a lamp, luminaire or lighting system.

The at least one light emitting diode can be potted in particular by means of a light-transmissive potting compound including at least one wavelength-converting phosphor.

Various embodiments further provide a method for producing a lighting device, at least including: providing a housing, the front side of which is provided for arranging at least one semiconductor light source, at the rear side of which housing a receptacle for accommodating the printed circuit board is present, and which housing has, between the front side and the rear side, at least one channel for leading through at least one electrical conduction element; providing a printed circuit board having at least one elongate electrical conduction element at a location corresponding to at least one channel of the housing; and combining the housing and the printed circuit board, wherein the at least one conduction element is inserted into the corresponding channel.

This method can be implemented particularly simply and inexpensively and produces a compact lighting device.

The method can be configured in particular analogously to the lighting device, e.g. by use of a multilayer printed circuit board within which at least one electrical or electronic component is arranged.

In one configuration, the step of combining is followed by a step of potting the printed circuit board in the receptacle. Potting is inexpensive and enables the printed circuit board to be received in the housing fixedly and in a manner protected against dust and moisture. The step of potting can include curing the potting compound.

In another configuration, the at least one conduction element is embodied as at least one electrically conductive pin and the step of combining is followed by a step of electrically connecting, in particular wire bonding, the at least one pin to an associated contact zone of the housing.

In another configuration, the method includes a step of populating the housing with the at least one semiconductor light source, in particular in the form of a bare chip (“bare dies”). The step of populating can be carried out, in particular, before the step of providing or after the step of potting.

In another configuration, the method includes a step of wiring, by means of which an electrical connection is produced between the printed circuit board and the at least one semiconductor light source, e.g. a step of bonding, in particular wire bonding. Alternatively or additionally, the wiring may include a step of soldering. The step of wiring can be carried out, in particular, after the step of populating the housing with the at least one semiconductor light source.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows as a sectional illustration in side view a lighting device in accordance with a first embodiment; and

FIG. 2 shows as a sectional illustration in side view a lighting device in accordance with a second embodiment.

### DETAILED DESCRIPTION

The following detailed description refers to the accompanying drawing that show, by way of illustration, specific details and embodiments in which the disclosure may be practiced.

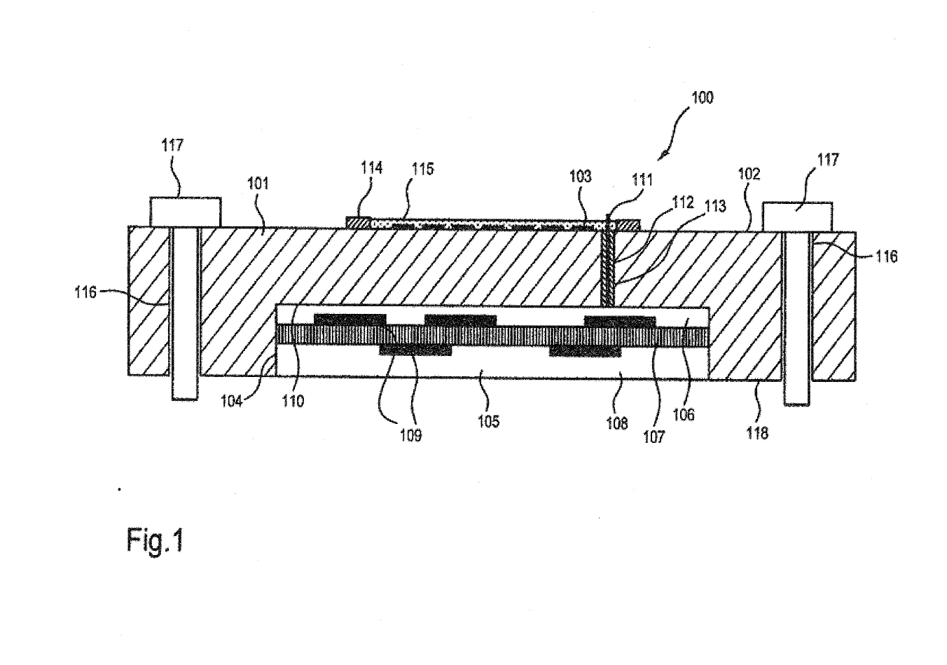

FIG. 1 shows as a sectional illustration in side view a lighting device in the form of an LED module 100 in accordance with a first embodiment.

The LED module 100 includes a housing 101 composed of aluminum, at the front side 102 of which a plurality of semiconductor light sources in the form of light emitting diode chips 103 are arranged and at the rear side 118 of which a receptacle 104 for accommodating a printed circuit board 105 is present.

The printed circuit board 105 is configured as a multilayer printed circuit board having three layers, namely having an outer or exterior upper layer 106, an intermediate layer 107 and an outer or exterior lower layer 108. Electrical and/or electronic components 109 serving for operating the light emitting diode chips 103 are arranged between the upper layer 106 and the intermediate layer 107 and also between the intermediate layer 107 and the lower layer 108. The components 109 can be printed components 109 or components 109 embedded into the printed circuit board 105 in some other way, in particular unhoused components 109. An accurate and identical fitting of the printed circuit board 105 into the receptacle 104 can thus be made possible even for different and differently wired components 109. This simplifies a utilization of concepts involving identical parts, e.g. with identical housings 101, and provides a particularly compact LED module 100.

The printed circuit board 105 was produced from a conventional (non-covered) printed circuit board, wherein the conventional printed circuit board includes the intermediate layer 107, which was populated with the components 109. The intermediate layer 107 can be, for example, a ceramic substrate, a metal-core circuit board, an FR circuit board or a CEM circuit board. The components 109 can also be conventional electrical and/or electronic components, wherein a flat design is generally preferred, e.g. a configuration as SMD devices or printed devices.

The conventional printed circuit board was subsequently fixedly covered on both sides by the upper layer 106 and the lower layer 108, respectively. For this purpose, the upper layer 106 and the lower layer 108 are embodied as prepreg layers. For connecting a wiring of the intermediate layer 107 and thus of the components 109 at least one printed circuit board plated-through hole is led (not illustrated) through the upper layer 106. Electrical contact can therefore be made from outside with the (covered) printed circuit board 105 at the top side 110 thereof or at the upper layer 106 by means of the printed circuit board plated-through hole(s).

In order to allow the printed circuit board 105 to make electrical contact with a power supply and also with the light emitting diode chips 103, the printed circuit board 105 has, at its top side 110, at least one electrical conduction element in the form of a vertically projecting pin 111 composed of an electrically conductive material. The pin 111 extends through a respective channel 112 in the housing 101 and is fixed to the printed circuit board 105 by means of a press-fit connection. The channel 112 is embodied here as a vertical drilled hole running from the receptacle 104 to the front side 102 of the housing 101. For the purpose of electrical insulation between the pin 111 and the housing 101, the pin 111 is surrounded by an electrically insulating sleeve 113, e.g. composed of glass, at least within the housing 101. The pin 111 can be electrically connected to the light emitting diode chips 103 by wire bonding, soldering, etc. In particular, the pin 111 can have a width such that its upper top area (facing away from the printed circuit board 105) can serve as a bondable plane for fixing a bonding wire.

The light emitting diode chips 103 are surrounded by a circumferential ring 114 bearing on the front side 102 of the housing 101. The ring 114 serves as a lateral boundary during a potting of the light emitting diode chips 103 with a potting compound 115. The potting compound 115 can comprise, for example, a diffusely scattering filling material and/or at least one wavelength-converting phosphor (“Remote Phosphor”).

The housing 101 furthermore has vertical, continuous screw holes 116 arranged outside the receptacle 104 and outside the ring 114, into which screw holes screws 117 can be led from the front side 102 for the screwing fixing of the LED lighting module 100, e.g. for screwing to a heat sink (not illustrated).

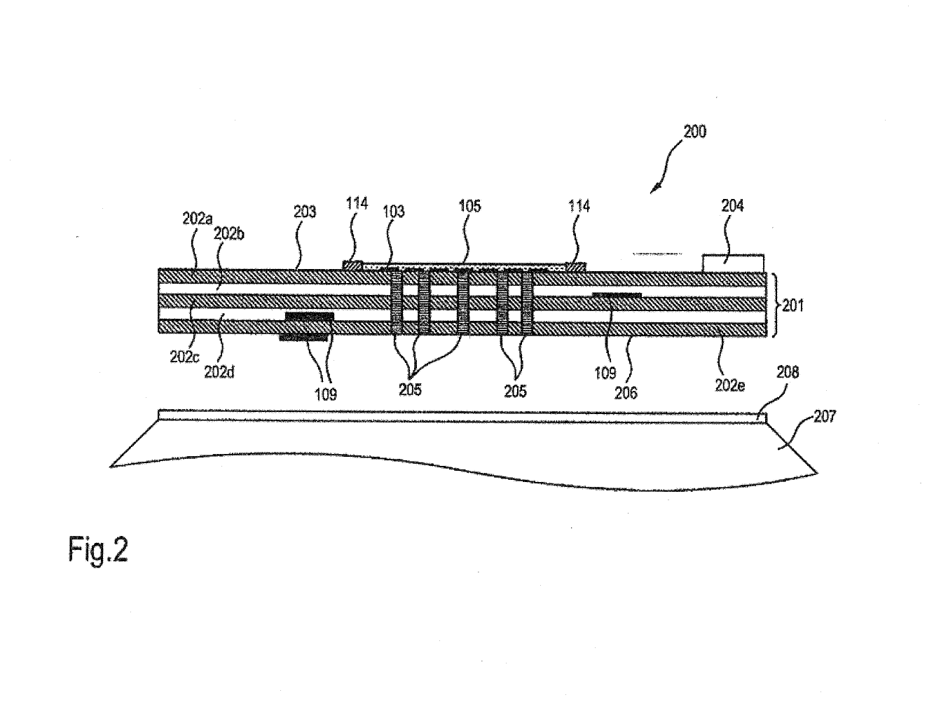

FIG. 2 shows as a sectional illustration in side view a lighting device in the form of an LED module 200 in accordance with a second embodiment.

The LED module 200 includes a multilayer printed circuit board 201 consisting of five identical ceramic layers 202. The ceramic layers 202a to 202e were connected, in particular fired or sintered, to one another by means of an LTCC method.

Components 109 are arranged, e.g. embedded or printed, on the central ceramic layer 202c and on the lower ceramic layer 202e. The components 109 situated between two ceramic layers 202b and 202c, or 202d and 202e, preferably have a small or negligible structural height. Particularly the component 109 situated on the outer side of the lower layer 202e is preferably unhoused, in particular printed.

The light emitting diode chips 103 are arranged directly on a front side 203 of the printed circuit board 201 (electrically insulating and having good thermal conductivity), to be precise similarly to the LED module 100 with a ring 114 and a potting compound 115. In addition, an electrical connection element 204, e.g. a plug connector, for connection to an electrical supply is present on the front side 203. The connection element 204 is electrically connected to the electrical components 109 and further to the light emitting diode chips 103 via, in particular silver-filled, printed circuit board plated-through holes 205.

For fixing the lighting module 200, the latter here is connected by its rear side 206 or that of the printed circuit board 201 areally to a heat sink 207, to be precise by means of a thermally conductive adhesive, which is present here in the form of a TIM (“Thermal Interface Material”) layer 208.

This lighting module 200 can be produced particularly compactly and inexpensively.

While the disclosed embodiments has been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

### LIST OF REFERENCE SIGNS

100 LED module
101 Housing
102 Front side of the housing
103 Light emitting diode chip
104 Receptacle
105 Printed circuit board
106 Upper layer of the printed circuit board
107 Intermediate layer of the printed circuit board
108 Lower layer of the printed circuit board
109 Electrical and/or electronic component
110 Top side of the printed circuit board
111 Pin
112 Channel
113 Electrically insulating sleeve
114 Ring
115 Potting compound
116 Screw hole
117 Screw
118 Rear side
200 LED module
201 Printed circuit board
202a-e Ceramic layer
203 Front side of the printed circuit board
204 Connecting element
205 Printed circuit board plated-through hole
206 Rear side of the printed circuit board
207 Heat sink
208 TIM layer

1. A lighting device, comprising
at least one semiconductor light source,
at least one printed circuit board which is populated with at least one component for operating the at least one semiconductor light source,
wherein
at least one component is embedded into the printed circuit board.

2. The lighting device as claimed in claim 1, wherein a plurality of components are embedded in the printed circuit board.

3. The lighting device as claimed in claim 1, wherein the at least one printed circuit board is a ceramic printed circuit board.

4. The lighting device as claimed in claim 3, wherein at least one component is printed onto the printed circuit board.

5. The lighting device as claimed in claim 1, wherein the at least one printed circuit board is a multilayer printed circuit board having prepreg layers on the outer side.

6. The lighting device as claimed in claim 1, wherein the at least one semiconductor light source is arranged at a side of the printed circuit board.

7. The lighting device as claimed in claim 1, wherein the lighting device further comprises a housing, at the front side of which the at least one semiconductor light source is arranged and at the rear side of which a receptacle for accommodating the printed circuit board is present.

8. The lighting device as claimed in claim 7, wherein the housing has at least one channel from the receptacle to the front side and the printed circuit board has at least one elongate electrical conduction element which is laid in at least one channel and which electrically connects the at least one component to the at least one semiconductor light source.

9. The lighting device as claimed in claim 8, wherein the elongate electrical conduction element is a pin.

10. The lighting device as claimed in claim 7, wherein the housing thermally conductive.

11. The lighting device as claimed in claim 1, wherein the lighting device is a lighting module.

12. A method for manufacturing a lighting device, at least comprising:
providing a housing, the front side of which is provided for arranging at least one semiconductor light source, at the rear side of which housing a receptacle for accommodating the printed circuit board is present, and which housing has, between the front side and the receptacle, at least one channel for leading through at least one electrical conduction element;
providing a printed circuit board having at least one elongate electrical conduction element at a location corresponding to at least one channel of the housing; and
combining the housing and the printed circuit board, wherein the at least one conduction element is inserted into the corresponding channel.

13. The method as claimed in claim 12, wherein the combining is followed by potting the printed circuit board in the receptacle.

14. The method as claimed in claim 12, wherein the at least one conduction element is embodied as at least one electrically conductive pin and the combining is followed by electrically connecting, the at least one pin to an associated contact zone of the housing.

15. The method as claimed in claim 12, wherein the method furthermore comprises populating the housing with the at least one semiconductor light source.

16. The lighting device as claimed in claim 1, wherein the at least one semiconductor light source is a light emitting diode.

17. The lighting device as claimed in claim 3, wherein the at least one printed circuit board is an LTCC multilayer printed circuit board.

18. The lighting device as claimed in claim 9, wherein the pin is bondable.
